(19) United States
(12) Patent Application Publication
(10) Pub. No.: US 2017/0359153 A1
(43) Pub. Date: Dec. 14, 2017

(54) MEASURING DELAY LINE LINEARITY CHARACTERISTICS

(71) Applicant: FUJITSU LIMITED, Kawasaki-shi (JP)

(72) Inventors: Daisuke USUI, Cupertino, CA (US); Masaya KIBUNE, Santa Clara, CA (US); Nikola NEDOVIC, San Jose, CA (US)

(73) Assignee: FUJITSU LIMITED, Kawasaki-shi (JP)

(21) Appl. No.: 15/182,567

(22) Filed: Jun. 14, 2016

(51) Int. Cl. H04L 1/20; H03K 5/24; H04L 7/00; H03K 5/06

(52) U.S. Cl. CPC H04L 1/203; H03K 5/06; H03K 5/24; H04L 7/0012

(57) ABSTRACT

A method of measuring linearity characteristics of a delay line may be provided. The method may include generating an output signal from a receiver including a delay line. The method may also include measuring linearity characteristics of the delay line based on a target performance parameter of the output signal.

### FIELD

The embodiments discussed herein are related to measuring linearity characteristics of a delay line.

### BACKGROUND

Delay line circuits may be used to provide predetermined amounts of delay for electrical signals. More specifically, for example, an electronic receiver may receive a data signal and a reference clock signal. A delay line circuit within the receiver may receive the reference clock signal and generate a sampling clock signal having a phase that is shifted to the center of the data signal.

The subject matter claimed herein is not limited to embodiments that solve any disadvantages or that operate only in environments such as those described above. Rather, this background is only provided to illustrate one example technology area where some embodiments described herein may be practiced.

### SUMMARY

One or more embodiments of the present disclosure include a method of measuring linearity characteristics of a delay line. One method may include generating an output signal from a receiver including a delay line. The method may further include measuring linearity characteristics of the delay line based on a target performance parameter of the output signal.

The object and advantages of the embodiments will be realized and achieved at least by the elements, features, and combinations particularly pointed out in the claims. Both the foregoing general description and the following detailed description are exemplary and explanatory and are not restrictive.

### BRIEF DESCRIPTION OF THE DRAWINGS

Example embodiments will be described and explained with additional specificity and detail through the use of the accompanying drawings in which:

FIG. 1A depicts a device including a receiver and a bit error rate tester;

FIG. 1B illustrates an input data signal and a sampling clock signal generated from a reference clock;

FIG. 1C depicts a delay line;

FIG. 1D is a phase code versus delay plot;

FIG. 2A is a block diagram of a device including a receiver, a bit error rate tester, and external measuring equipment;

FIG. 2B is a block diagram of a device including a receiver, a bit error rate tester, and an internal measuring circuit;

FIG. 3 depicts a bit error rate tester;

FIG. 4 depicts a device including a receiver having a delay selector;

FIG. 5A depicts a sampling clock and a shifted sampling clock by phase code;

FIG. 5B depicts an input data signal and a shifted input data signal;

FIG. 5C depicts bit error rates associated with the phase codes of FIG. 5A;

FIG. 6 is a flowchart of an example method for measuring linearity characteristics of a delay line;

FIG. 7 depicts a sampling clock of a phase code, an input data, and an associated bit error rate;

FIG. 8 is a phase code versus input data phase plot;

FIG. 9A depicts an eye diagram of a signal without jitter;

FIG. 9B depicts an eye diagram of a signal with jitter;

FIG. 9C depicts a histogram of total jitter of a signal;

FIG. 10A depicts an example bath tub plot of a bit error rate;

FIG. 10B depicts an example bath tub plot of Q values;

FIG. 11A depicts a sampling clock of a phase code;

FIG. 11B depicts two measured Q values and an interpolated Q value;

FIG. 11C depicts a shifted input data signal;

FIG. 12A depicts sampling clock of a phase code;

FIG. 12B depicts two measured Q values and an extrapolated Q value;

FIG. 12C depicts shifted input data signal phases;

FIGS. 13A and 13B are a flowchart of an example method for measuring linearity characteristics of a delay line circuit;

FIG. 14 illustrates a sampling clock of a phase code, an input data, a plurality of measured Q values, a calculated Q value, and a calculated input data phase;

FIG. 15 illustrates a bath tub plot of a Q value; and

FIG. 16 is a block diagram of an example electronic device.

### DESCRIPTION OF EMBODIMENTS

The present disclosure relates to measuring linearity characteristics of a delay line circuit. In one embodiment, linearity characteristics of a delay line are measured based on a bit error rate (BER) (e.g., of a receiver). In this embodiment, a phase code, a phase of an input data signal, or both, may be modified to generate target BERs (e.g., within a BER range). Stated another way, a phase code and/or a phase of the input data signal may be changed to generate target BERs. Phase code values and corresponding input data phases for generated target BERs may be used to determine a performance characteristic (e.g., linearity characteristics) of the delay line. More specifically, an output signal of a delay line for a plurality of received input data phase signals across a range of received phase codes may provide linearity characteristics of the delay line. Yet, more specifically, an output signal of the delay line may be compared (e.g., on a plot) to a target output signal (e.g., ideal performance parameter) of the delay line for a plurality of received input data phase signals across a range of received phase codes to determine the linearity characteristics of the delay line.

In another embodiment, linearity characteristics of a delay line are measured based on a Q-scale (e.g., of a receiver). In this embodiment, a phase code, a phase of an input data signal (e.g., a jittery input data signal), or both, may be modified to generate target Q-values (e.g., within a Q-value range). Stated another way, a phase code and/or a phase of the input data signal may be changed to generate target Q-values. Phase code values and corresponding input data phases for generating target Q-values may be used to determine the linearity characteristics of the delay line. For example, a plot of phase code versus phase of the input data signal may provide linearity characteristics of the delay line.

Embodiments of the present disclosure are now explained with reference to the accompanying drawings.

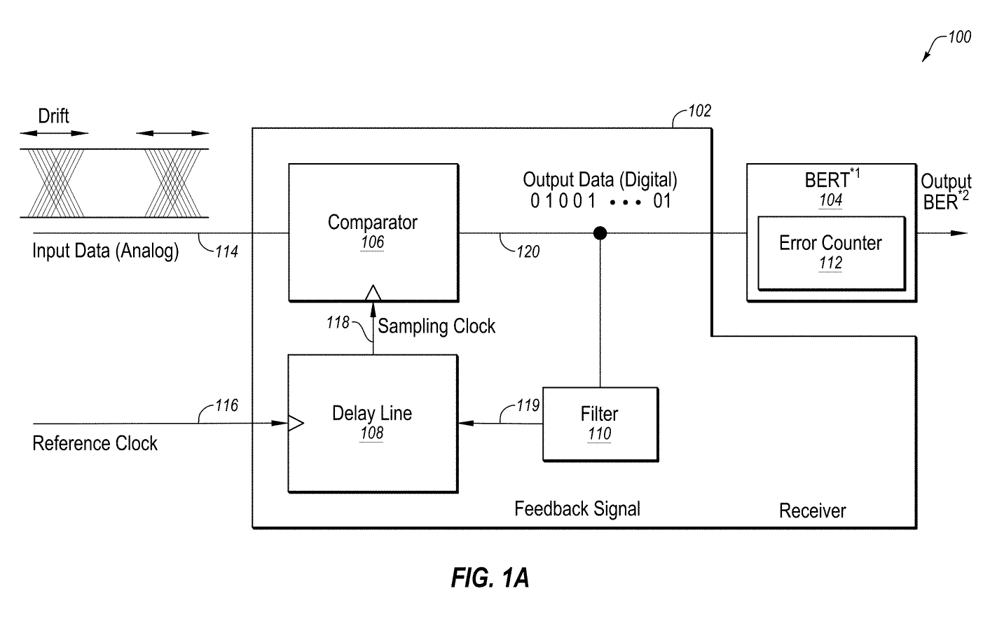

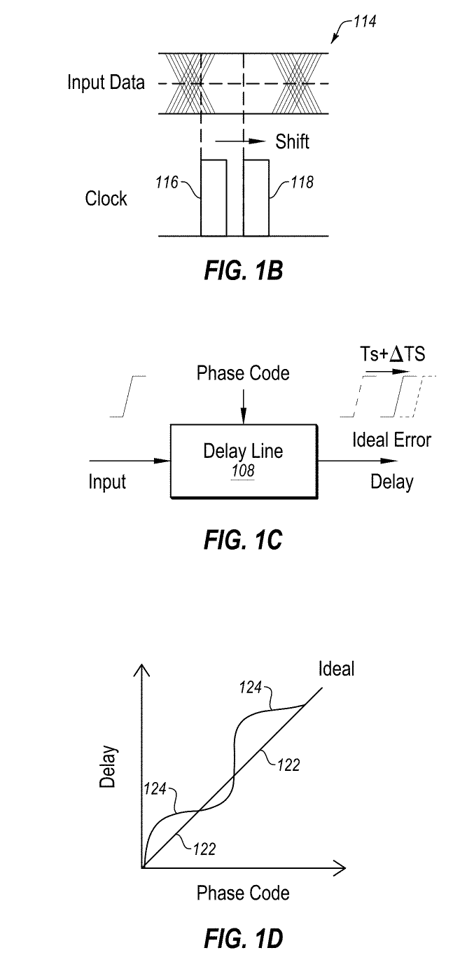

FIG. 1A depicts a device 100 including a receiver 102 and a bit error rate tester (BERT) 104. Receiver 102 includes a comparator 106, a delay line 108, and a filter 110. BERT 104 includes an error counter 112. During operation of device 100, comparator 106 may receive an input data signal (e.g., an analog signal) 114, and delay line 108 may receive a reference clock signal 116 and a feedback signal 119. Further, delay line 108 may generate a sampling clock signal 118 from reference clock signal 116. Delay line 108 may convey sampling clock signal 118 to comparator 106. As illustrated in FIG. 1B, a phase of sampling clock signal 118 may be shifted, relative to reference clock signal 116, to the center of input data signal 114. With reference again to FIG. 1A, comparator 106 may convert input data signal 114 to an output data signal (e.g., a digital signal) 120 using sampling clock signal 118.

FIG. 1C depicts delay line 108, which is configured to receive an input signal (e.g., reference clock signal 116) and a phase code, and convey an output signal (e.g., sampling clock signal 118). An output signal of a delay line 108 may include some error, as illustrated in FIG. 1C. FIG. 1D is phase code versus delay (e.g., output of delay line 108) plot 120 illustrating an ideal response 122 and an actual response 124. The linearity characteristics of delay line 105 (see FIG. 1A), as depicted by plot 120, may affect the performance of receiver 102.

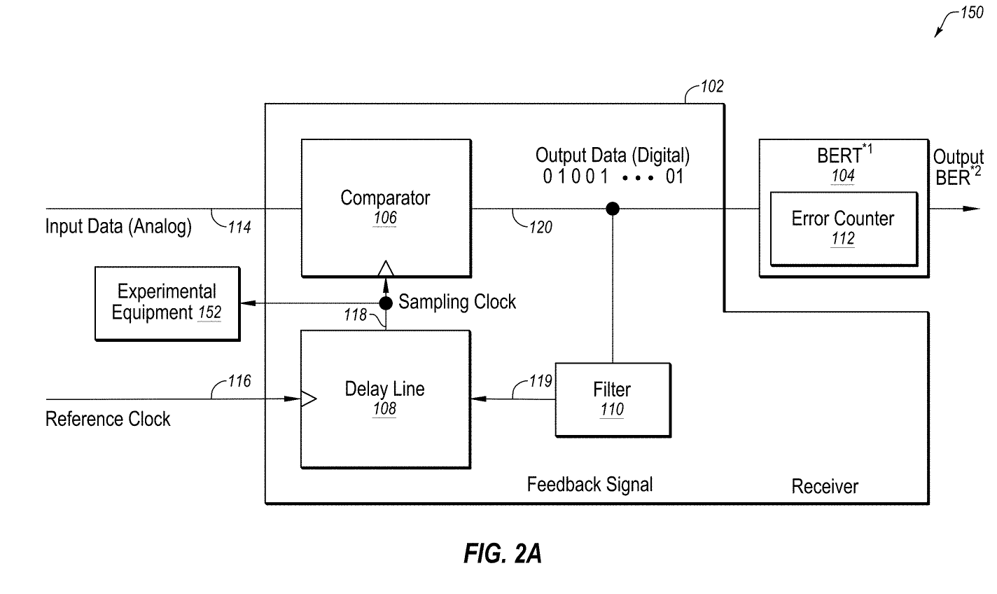

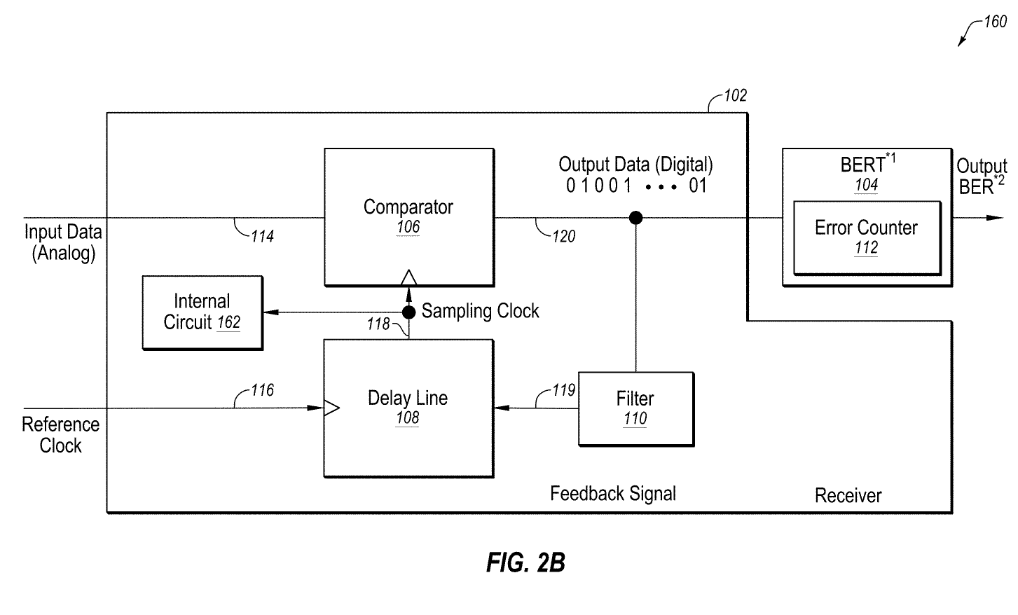

FIGS. 2A and 2B depict devices 150 and 160, respectively, including additional circuitry for measuring a sampling clock signal. More specifically, device 150 includes an external device 152 for measuring a sampling clock signal, and device 160 includes an internal device 162 for measuring a sampling clock signal. External device 152 and internal device 162 may require large areas and may undesirably affect the sampling clock signal.

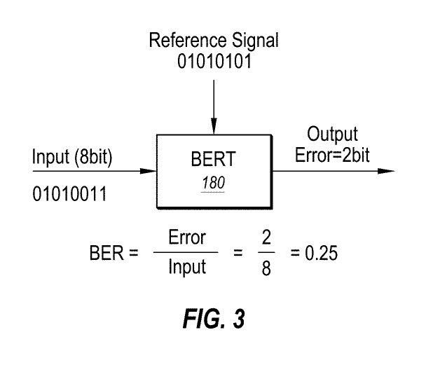

Various embodiments disclosed herein are related to measuring linearity characteristics of a delay line via a bit error rate (BER). A BER is the number of error bits divided by the total number of transferred bits. A BER may be determined by a BERT 180 as shown in FIG. 3. For example, if the total number of transferred bits is equal to 8 and the number of error bits is equal to 2, the BER is equal to 0.25 ( 2/8).

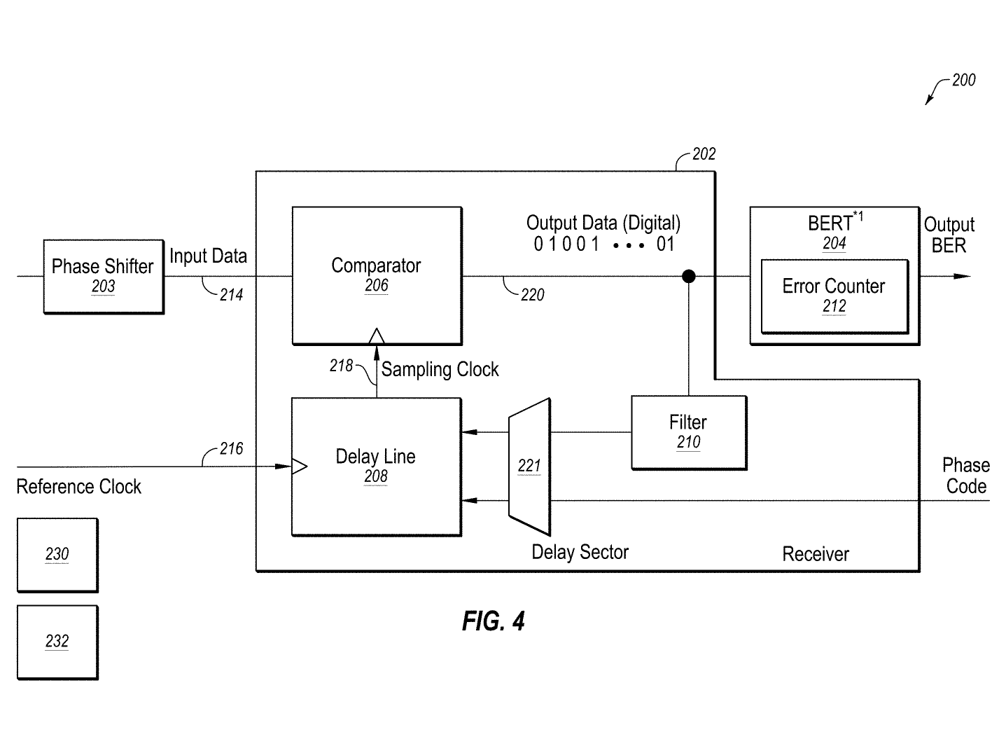

FIG. 4 illustrates a device 200 including a receiver 202, a phase shifter 203, and a BERT 204. Device 200 may also include a controller 230 and memory 232. Receiver 202 includes a comparator 206, a delay line 208, and a filter 210.

Receiver 202 further includes a delay selector 221, which is configured to receive a signal from filter 210 and a phase code. Delay selector 221 is further configured to convey one or more signals (e.g., filtered feedback signal via filter 210 and/or a phase code) to delay line 208. BERT 204 includes an error counter 212. Although BERT 204 is depicted as being external to receiver 202, BERT 204 may be internal to receiver 202.

During a contemplated operation of device 200, phase shifter 203 may receive a signal, and delay the received signal to generate an input data signal 214, which is phase shifted relative to the signal received by phase shifter 203. Input data signal 214 may include a phase, which may be referred to herein as an “input data phase” or a “phase of an input data signal.” Phase shifter 203 may be calibrated and a phase of input data signal 214 may be highly accurate.

Comparator 206 may receive input data signal (e.g., an analog signal) 214, and delay line 208 may receive a reference clock signal 216. Further, delay line 208 may generate a sampling clock signal 218, which may be conveyed to comparator 206. Comparator 206 may convert input data signal 214 to an output signal (e.g., a digital signal) 220 using sampling clock signal 218. Output signal 220 may be received by BERT 204, which may determine a BER of output signal 220.

Controller 230 may be configured to determine a performance parameter (e.g., BER, Q-value, etc.) of delay line 208 based on the BER of the output signal, and adjust the input data phase and/or the phase code (e.g., to generate the performance parameter within a target range). Controller 230 may further be configured to measure linearity characteristics of delay line 208 based on each input data phase-phase code combination to generate the performance parameter within the target range. Memory 232 may be configured to store data, such as data related to input data phases, phase codes, BERs, Q values, etc.

In one embodiment, the phase code and the phase of the input data may be controlled externally. Further, error counter 212 may include a relatively small circuit (e.g., due to low bit error rate).

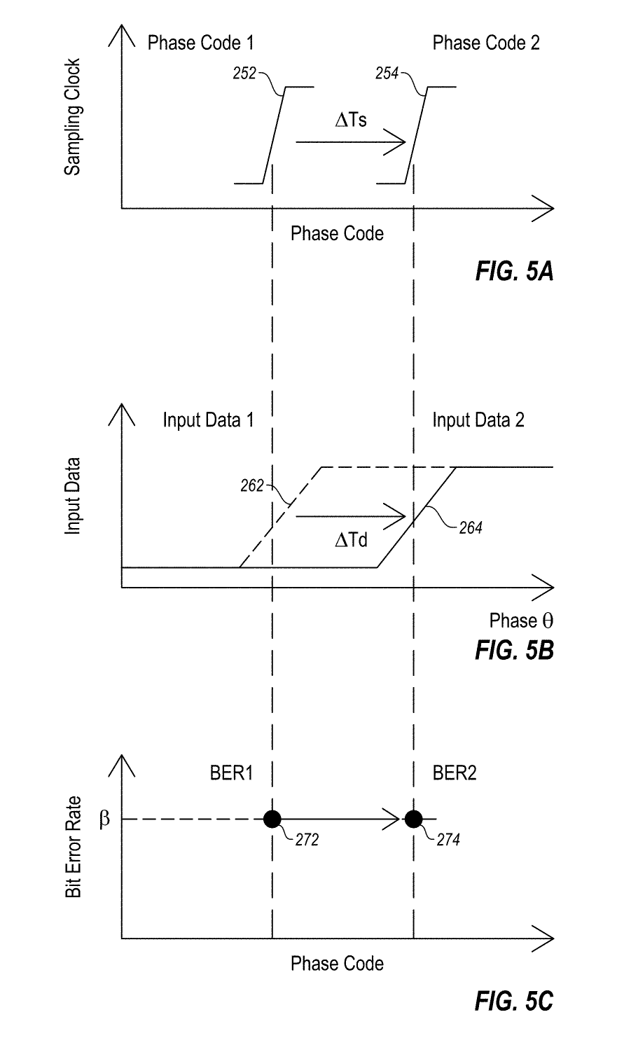

FIG. 5A depicts a sampling clock at a phase code 252 and a sampling clock at a phase code 254 shifted by ΔTs. FIG. 5B depicts an input data signal 262, and an input data signal 264 having a phase shifted by ΔTd. FIG. 5C depicts a BER 272 and a BER 274. For example, a BER measurement at phase code 252 and input data phase 262 may be BER 272. Further, a BER measurement at phase code 254 and input data phase 264 may be BER 274. It is noted that if the sampling clock resolution ΔTs is equal to the input data phase step ΔTd, BER 272 may be equal to BER 274.

In accordance with various embodiments, linearity characteristics of a delay line (e.g., delay line 208) may be evaluated without additional circuitry except for a delay selector (e.g., delay selector 221 of FIG. 4). Therefore, area and cost may be reduced compared to conventional devices.

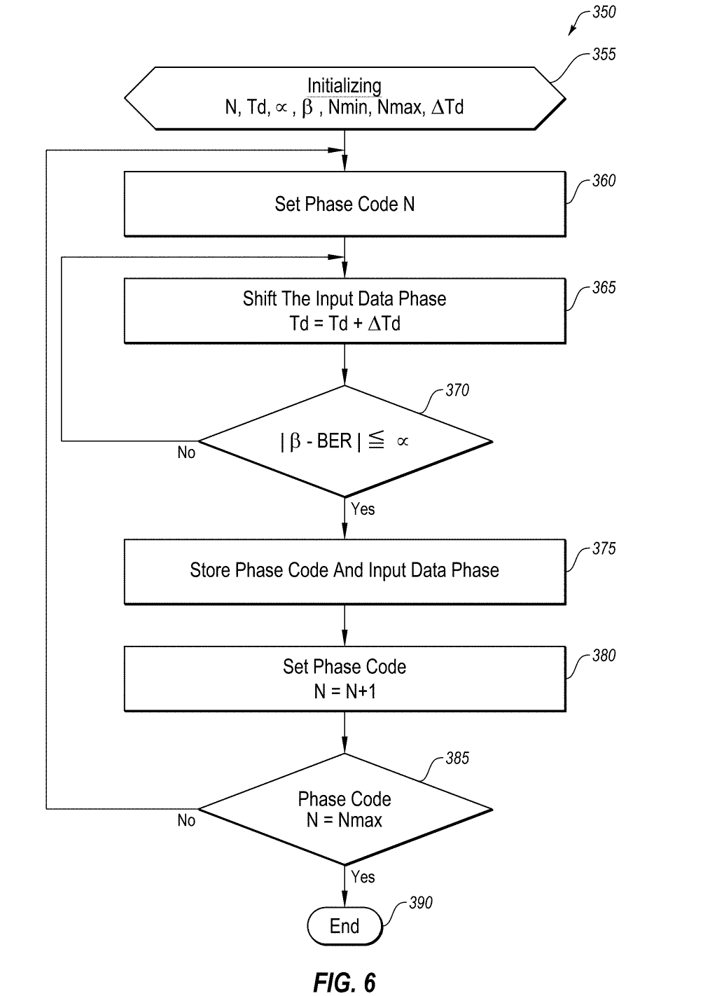

FIG. 6 is a flowchart of an example method 350 for measuring linearity characteristics of a delay line circuit, in accordance with at least one embodiment of the present disclosure. Method 350 may be performed by any suitable system, apparatus, or device. For example, device 200 of FIG. 4 or one or more of the components thereof may perform one or more of the operations associated with method 350. In these and other embodiments, program instructions stored on a computer readable medium may be executed to perform one or more of the operations of method 350.

At block 355, one or more variables may be initialized (e.g., via controller 230 of FIG. 4). For example, one or more of an initial phase code N, an initial input data phase Td, a margin α, a BER threshold β, a phase code minimum Nmin, a phase code maximum Nmax, and an input data phase step ΔTd may be initialized. As non-limiting examples, margin α<±1, log₁₀(10^{±1}) and BER threshold β≦−7, log₁₀(10⁻⁷). Method 350 may proceed to block 360.

At block 360, an initial phase code N may be set, and method 350 may proceed to block 365.

At block 365, a phase of an input data signal may be shifted (e.g., Td=Td+ΔTd). For example, with reference to FIG. 4, phase shifter 203 may receive a control signal from controller 230 to shift a phase of the input data signal. Method 350 may proceed to block 370.

At block 370, a determination as to whether an absolute value of the BER threshold β minus a measured BER is less than or equal to margin α(|β−BER|<=α). As an example, controller 230 may determine whether an absolute value of the BER threshold β minus the measured BER is less than or equal to margin α(|β−BER|<=α). If the absolute value of the BER threshold β minus the measured BER is less than or equal to margin α, method 350 may proceed to block 375. If the absolute value of the BER threshold β minus the measured BER is not less than or equal to margin α, method 350 may return to block 365.

At block 375, the phase code and the input data phase may be stored. For example, the phase code and the input data phase may be stored in memory 232 of FIG. 4. Method 350 may proceed to block 380.

At block 380, the phase code N may be set to N+1 (e.g., via controller 230), and method 350 may proceed to block 385.

At block 385, a determination as to whether the phase code N is equal to Nmax. For example, controller 230 may determine whether the phase code N is equal to Nmax. If the phase code N is equal to Nmax, method 350 may terminate at block 390. If the phase code N is not equal to Nmax, method 350 may return to block 360.

Modifications, additions, or omissions may be made to method 350 without departing from the scope of the present disclosure. For example, the operations of method 350 may be implemented in differing order. Furthermore, the outlined operations and actions are only provided as examples, and some of the operations and actions may be optional, combined into fewer operations and actions, or expanded into additional operations and actions without detracting from the essence of the disclosed embodiments.

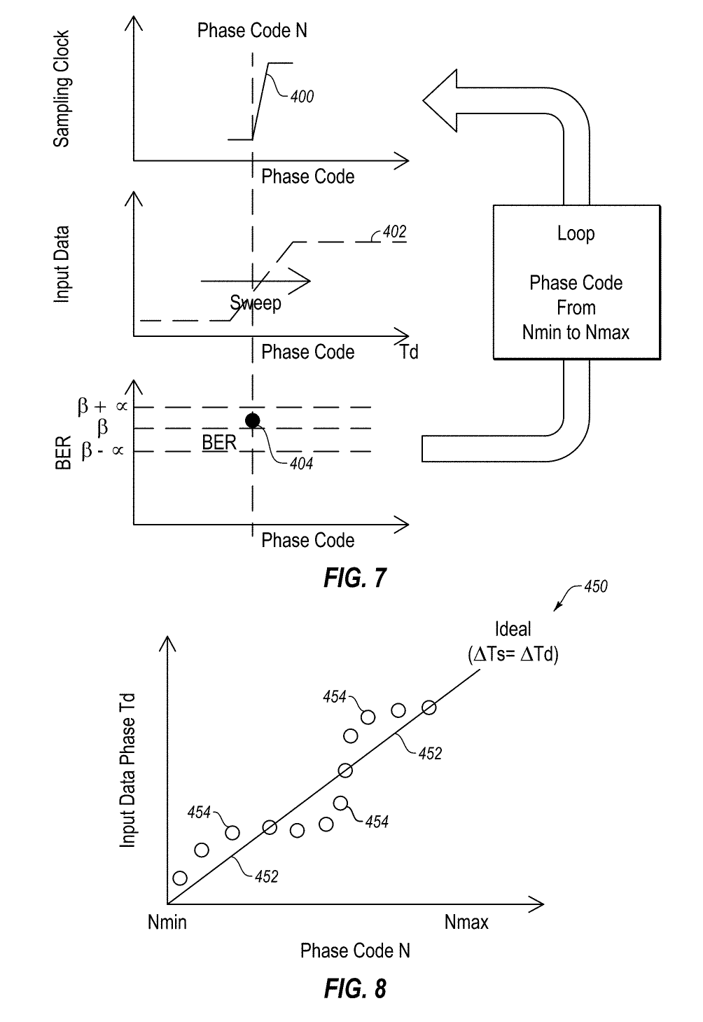

FIG. 7 illustrates a sampling clock at a phase code 400, an input data signal 402, and a BER 404. For each phase code 400 from minimum phase code Nmin to maximum phase code Nmax, a phase of input data signal 402 is shifted until a target BER 404 measurement is obtained. Stated another way, a phase “sweep” of input data signal 402 is performed at each phase code to obtain a target BER measurement (e.g., with a BER range). As an example, ΔTs<ΔTd/10. Stated another way, the input data phase may be adjusted up to 1/10 of a resolution of a sampling clock generated by a delay line (e.g., delay line 208 of FIG. 4).

FIG. 8 is a plot 450 of a phase code N across an input data phase Td to illustrate linearity characteristics of a delay line (e.g., delay line 208 of FIG. 4). Line 452 depicts linearity characteristics of an ideal delay line (ΔTs=ΔTd), and a curve formed by circles 454 depicts the linearity characteristics of an actual delay line.

A signal may have timing noise, which may be referred to as “timing jitter.” Jitter may defined as the short-term variation of a signal with respect to its ideal position in time. Jitter may include deterministic jitter and random Jitter. Deterministic jitter (DJ) is bounded jitter with a peak-to-peak value that may be predicted. Random jitter (RJ) is unbounded jitter and may be modeled with a Gaussian distribution.

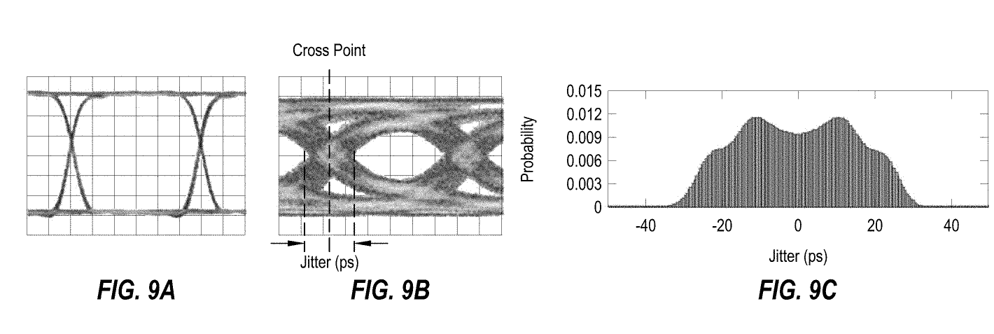

FIG. 9A depicts an eye diagram of a signal without jitter, FIG. 9B depicts an eye diagram of a signal with jitter, and FIG. 9C depicts a histogram of total jitter (DJ+RJ) of a signal.

Other embodiments of the present disclosure may relate to measuring linearity characteristics of a delay line via a Q-scale. For example, a phase code and a phase of jittery input data may be shifted to keep a particular value of Q. The particular value of Q can be calculated by two or more measured Q values using linearly approximation at high values of Q. Calculating a particular value of Q by linearly approximation may increase the accuracy of measuring linearity characteristics via a Q-scale.

When the input data has a larger random jitter with Gaussian distribution, compared with the deterministic jitter, a BER may be converted to a Q-value using the following equation:

$$Q = \sqrt{2} {erf}^{- 1} [ 1 - \frac{1}{{ρ}_{T}} BER ] ;$$

wherein erf⁻¹ is an inverted error function and ρr is the transition density (e.g., ρT=0.5 when the input data is non-return-zero (NRZ) data).

If the random jitter is smaller than the deterministic jitter, additional jitter may be applied externally on the input data and/or the sampling clock. Additional jitter may be added externally on the input data and/or the sampling clock if the slope is not linear dependent on time.

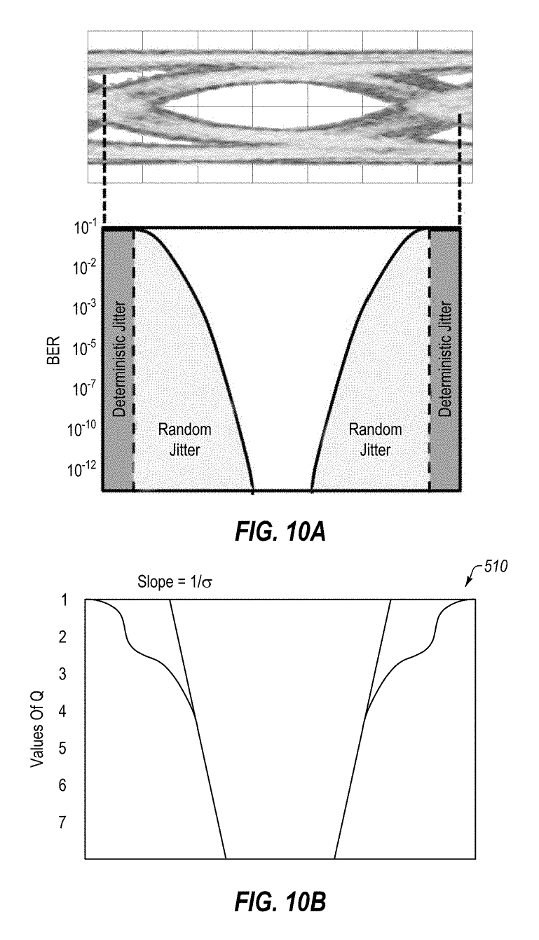

FIG. 10A depicts an example bath tub plot of BER 500, and FIG. 10B depicts an example bath tub plot of Q-scale 510.

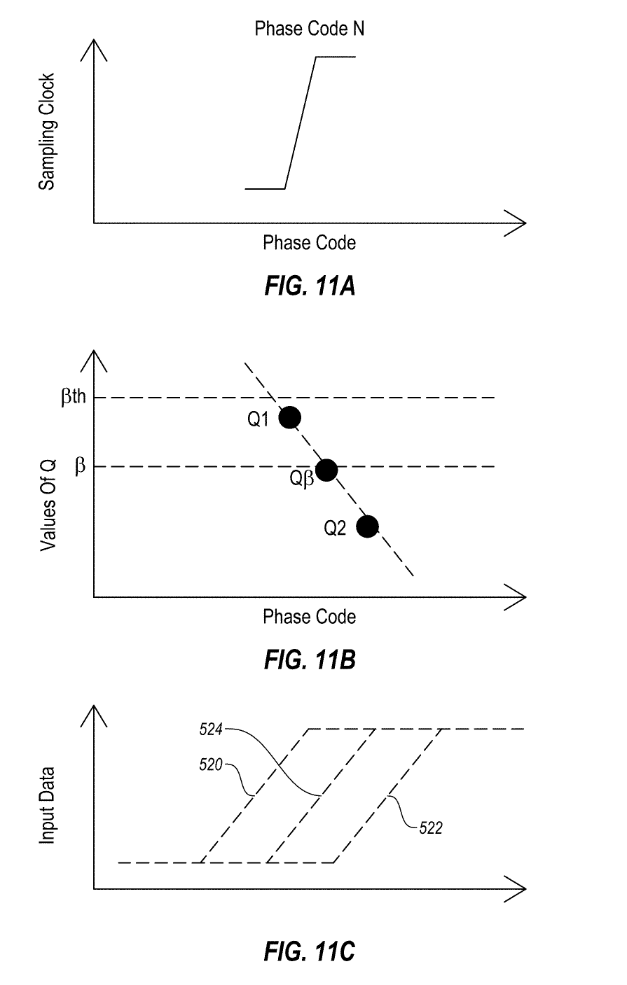

In accordance with various embodiments, two or more values of Q may be measured and calculated by shifting the phase code and the input data phase. FIG. 11A depicts a sampling clock at a phase code N, FIG. 11B depicts two measured Q values Q1 and Q2, and FIG. 11C depicts two input data signals 520 and 522 at different phases. Further, FIG. 11B depicts a target value of Q at β (e.g., Q_{β} as depicted in FIG. 11B) that may be calculated by interpolating measured Q values Q1 and Q2. Further, the input data signal 524 at the determined phase corresponding to Q value Q_{β} is also depicted in FIG. 11C.

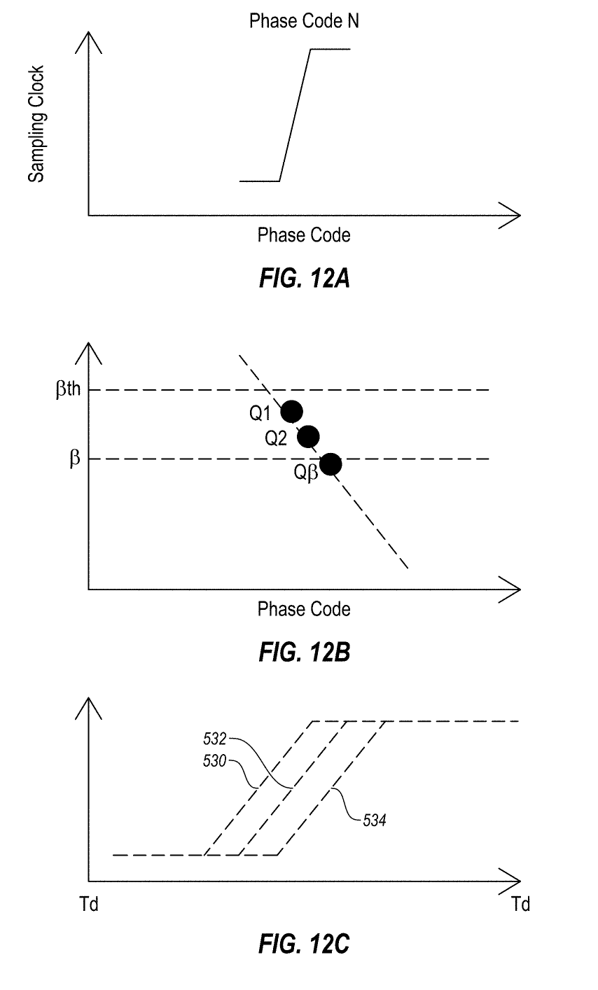

FIG. 12A-12C depicts another example in which FIG. 12A depicts a sampling clock at a phase code N, FIG. 12B depicts two measured Q values Q1 and Q2, and FIG. 11C depicts two input data 530 and 532 at different phases. Further, FIG. 12B depicts a target value of Q at β (e.g., Q_{β} as depicted in FIG. 12B) that may be calculated by extrapolating measured Q values Q1 and Q2. Further, the input data signal 534 at the determined phase corresponding to Q value Q_{β} is also depicted in FIG. 12C. Plotting phase code versus input data phase (e.g., phase code˜input data phase combinations that produce the target Q value Q_{β}) may provide the linearity characteristics of a delay line (e.g., delay line 208 of FIG. 4).

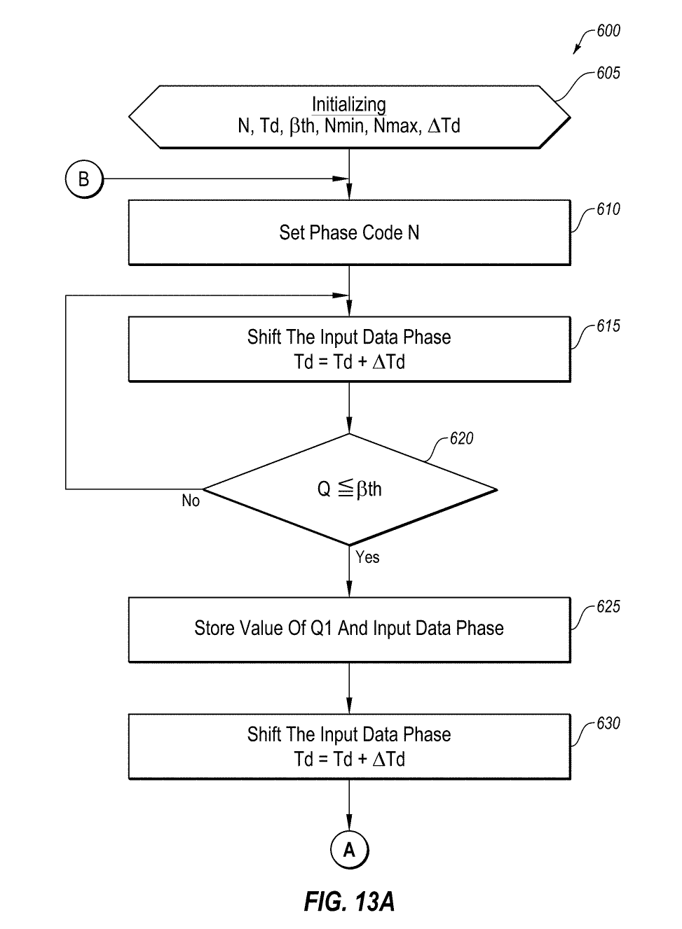

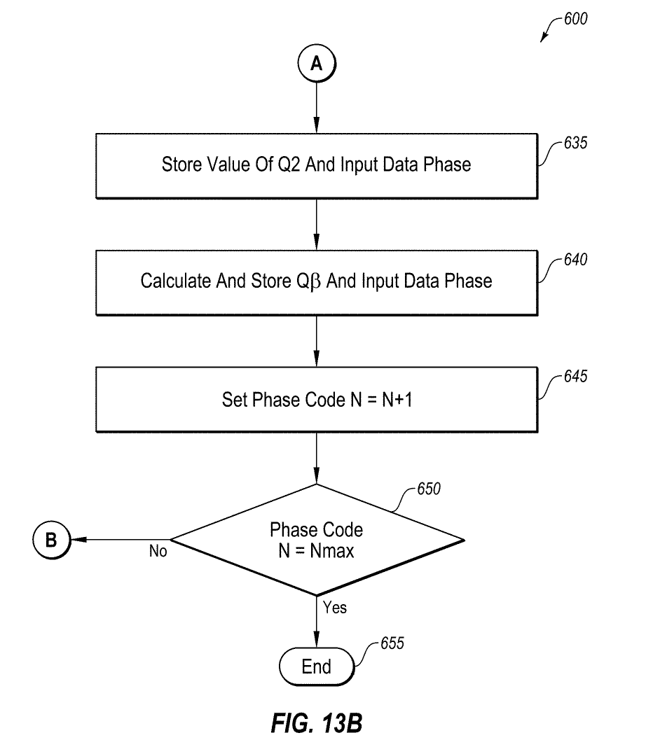

FIG. 13 is a flowchart of an example method 600 for measuring linearity characteristics of a delay line circuit, in accordance with at least one embodiment of the present disclosure. Method 600 may be performed by any suitable system, apparatus, or device. For example, device 200 of FIG. 4 or one or more of the components thereof may perform one or more of the operations associated with method 600. In these and other embodiments, program instructions stored on a computer readable medium may be executed to perform one or more of the operations of method 600.

At block 605, one or more variables may be initialized (e.g., via controller 230 of FIG. 4). For example, one or more of an initial phase code N, an initial input data phase Td, a threshold value βth, a phase code minimum Nmin, a phase code maximum Nmax, and an input data phase step ΔTd may be initialized, and method 600 may proceed to block 610.

At block 610, phase code N may be set (e.g., via controller 230 of FIG. 4), and method 600 may proceed to block 615.

At block 615, a phase of an input data signal may be shifted (e.g., Td=Td+ΔTd). For example, phase shifter 203 may receive a control signal from controller 230 (see FIG. 4) to shift a phase of the input data signal. Method 600 may proceed to block 620.

At block 620, a measured Q value Q1 may be determined (e.g., calculated via a measured BER), and a determination as to whether Q1 is less than or equal to threshold value βth. For example, controller 230 (see FIG. 4) may determine whether Q1 is less than or equal to threshold value βth. If Q1 is less than or equal to threshold value βth, method 600 may proceed to block 625. If Q1 is not less than or equal to threshold value βth, method 600 may return to block 615.

At block 625, the value of Q1 and the input data phase may be stored. For example, the value of Q1 and the input data phase may be stored in memory 232 (see FIG. 4). Method 600 may proceed to block 630.

At block 630, a phase of the input data signal may be shifted (e.g., Td=Td+ΔTd). For example, phase shifter 203 may receive a control signal from controller 230 (see FIG. 4) to shift a phase of the input data signal. Method 600 may proceed to block 635.

At block 635, a measured Q value Q2 may be determined, and the value of Q2 and the input data phase may be stored. For example, measured Q value Q2 may be determined via controller 230, and the value of Q2 and the input data phase may be stored in memory 230 (see FIG. 4). Method 600 may proceed to block 640.

At block 640, a target Q value Qβ and the corresponding input data phase may be calculated and stored. For example, target Q value Qβ and the corresponding input data phase may be calculated via controller 230, and target Q value Qβ and the input data phase may be stored in memory 232 (see FIG. 4). For example, target Q value Qβ is calculated from measured Q values Q1 and Q2. Method 700 may proceed to block 645.

At block 645, the phase code N may be set to N+1 (e.g., via controller 230), and method 600 may proceed to block 650.

At block 650, a determination as to whether the phase code N is equal to maximum phase code Nmax. By way of example, controller 230 may determine whether the phase code N is equal to maximum phase code Nmax. If the phase code N is equal to maximum phase code Nmax, method 600 may terminate at block 655. If the phase code N is not equal to maximum phase code Nmax, method 600 may return to block 610.

Modifications, additions, or omissions may be made to method 600 without departing from the scope of the present disclosure. For example, the operations of method 600 may be implemented in differing order. Furthermore, the outlined operations and actions are only provided as examples, and some of the operations and actions may be optional, combined into fewer operations and actions, or expanded into additional operations and actions without detracting from the essence of the disclosed embodiments.

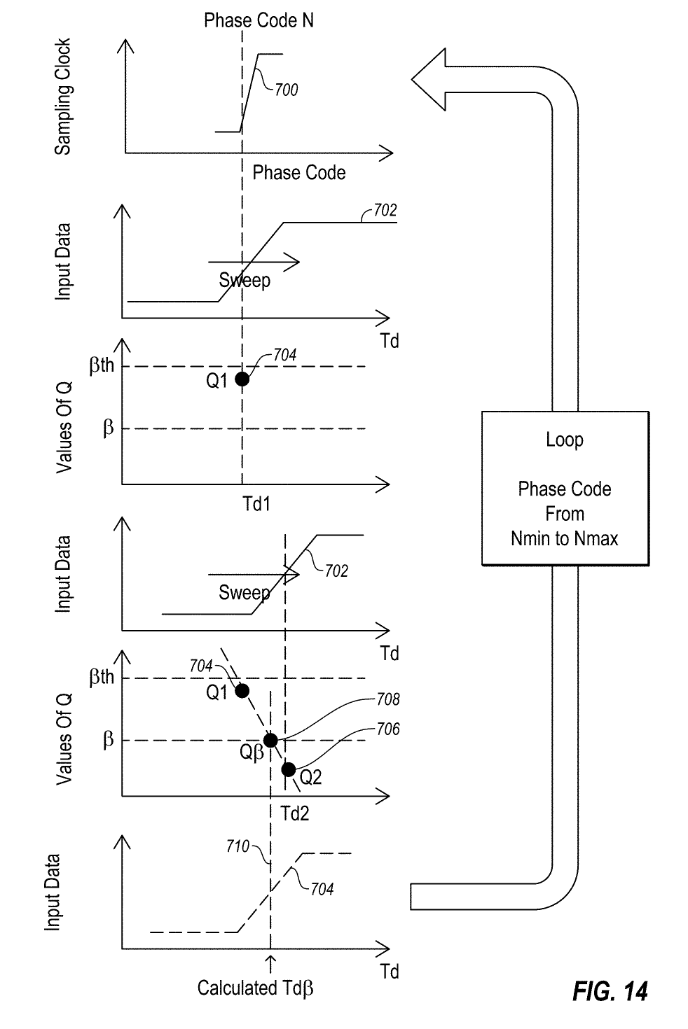

FIG. 14 illustrates a sampling clock at a phase code 700, an input data signal 702, and a measured Q value 704, a measured Q value 706, a target Q value 708 (derived from measured Q values 704 and 706), and input data signal 702 having a phase 710 corresponding to Q value 708. For each phase code 700 from minimum phase code Nmin to maximum phase code Nmax, an input data phase is shifted until two or more measured Q values less than or equal to threshold βth are obtained. Stated another way, a phase “sweep” of the input data signal is performed at each phase code to obtain two or more Q value measurements. Further, a target Q value Qβ is calculated based on the two or more measured Q values (e.g., via interpolation or extrapolation), and an input data phase associated with target Q value Qβ is calculated. Moreover, each phase code and the associated calculated input data phase may be used to measure the linearity characteristics of the delay line (e.g., delay line 208 of FIG. 4). More specifically, a plot of phase code versus calculated input data phase may provide the linearity characteristics of the delay line. As an example, ΔTs<ΔTd/8. Stated another way, the input data phase may be adjusted up to ⅛ of a resolution of a sampling clock generated by a delay line (e.g., delay line 208 of FIG. 4).

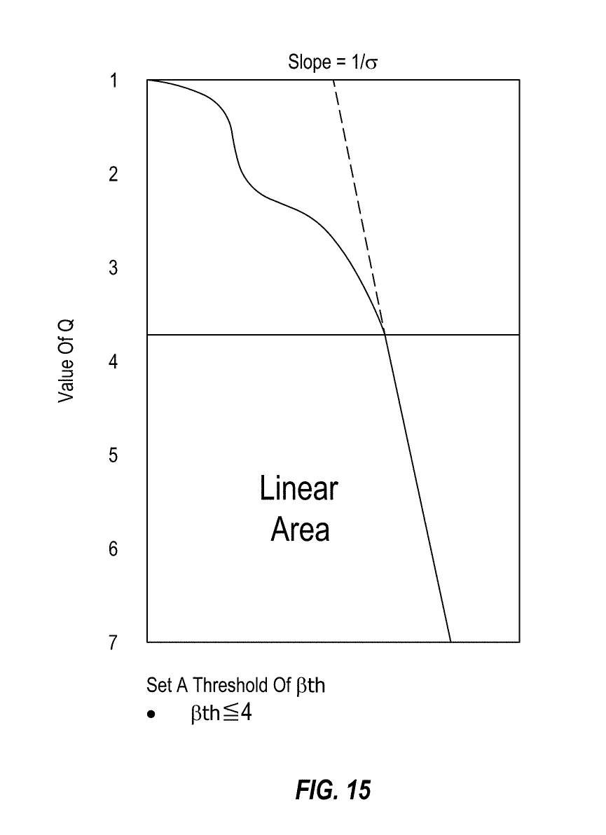

FIG. 15 depicts a bath tub plot of Q-values. As illustrated, a linear area is between a Q value of 4 and a Q value of 7. Thus, in this example, the threshold βth may less than or equal to 4.

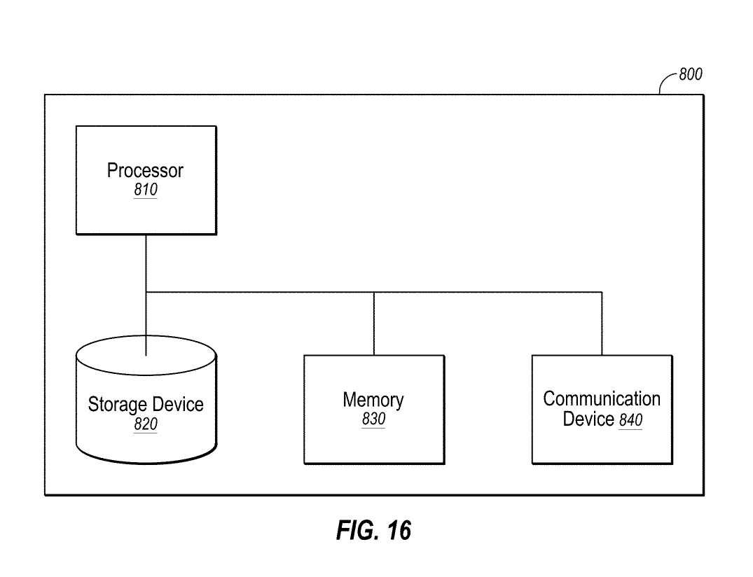

FIG. 16 is a block diagram of an example device 800, in accordance with at least one embodiment of the present disclosure. Any of phase shifter 203, receiver 202, BERT 204, comparator 206, delay line 208, and/or delay selector 221 of FIG. 4 may be implemented as device 800. Device 800 may include a desktop computer, a laptop computer, a server computer, a tablet computer, a mobile phone, a smartphone, a personal digital assistant (PDA), an e-reader device, a network switch, a network router, a network hub, other networking devices, or other suitable computing device.

Device 800 may include a processor 810, a storage device 820, a memory 830, and a communication component 840. Processor 810, storage device 820, memory 830, and/or communication component 840 may all be communicatively coupled such that each of the components may communicate with the other components. Device 800 may perform any of the operations described in the present disclosure.

In general, processor 810 may include any suitable special-purpose or general-purpose computer, computing entity, or processing device including various computer hardware or software modules and may be configured to execute instructions stored on any applicable computer-readable storage media. For example, processor 810 may include a microprocessor, a microcontroller, a digital signal processor (DSP), an application-specific integrated circuit (ASIC), a Field-Programmable Gate Array (FPGA), or any other digital or analog circuitry configured to interpret and/or to execute program instructions and/or to process data. Although illustrated as a single processor in FIG. 16, processor 810 may include any number of processors configured to perform, individually or collectively, any number of operations described in the present disclosure.

In some embodiments, processor 810 may interpret and/or execute program instructions and/or process data stored in storage device 820, memory 830, or storage device 820 and memory 830. In some embodiments, processor 810 may fetch program instructions from storage device 820 and load the program instructions in memory 830. After the program instructions are loaded into memory 830, processor 810 may execute the program instructions.

For example, in some embodiments one or more of the processing operations of a process chain may be included in data storage 820 as program instructions. Processor 810 may fetch the program instructions of one or more of the processing operations and may load the program instructions of the processing operations in memory 830. After the program instructions of the processing operations are loaded into memory 830, processor 810 may execute the program instructions such that device 800 may implement the operations associated with the processing operations as directed by the program instructions.

Storage device 820 and memory 830 may include computer-readable storage media for carrying or having computer-executable instructions or data structures stored thereon. Such computer-readable storage media may include any available media that may be accessed by a general-purpose or special-purpose computer, such as processor 810. By way of example, and not limitation, such computer-readable storage media may include tangible or non-transitory computer-readable storage media including RAM, ROM, EEPROM, CD-ROM or other optical disk storage, magnetic disk storage or other magnetic storage devices, flash memory devices (e.g., solid state memory devices), or any other storage medium which may be used to carry or store desired program code in the form of computer-executable instructions or data structures and which may be accessed by a general-purpose or special-purpose computer. Combinations of the above may also be included within the scope of computer-readable storage media. Computer-executable instructions may include, for example, instructions and data configured to cause the processor 810 to perform a certain operation or group of operations.

In some embodiments, storage device 820 and/or memory 830 may store data associated with measuring linearity characteristics of a delay line circuit. For example, storage device 820 and/or memory 830 may store phase codes, input data phases, measured Q values, calculated Q values, or any combination thereof.

Communication component 840 may include any device, system, component, or collection of components configured to allow or facilitate communication between device 800 and a network. For example, communication component 840 may include, without limitation, a modem, a network card (wireless or wired), an infrared communication device, an optical communication device, a wireless communication device (such as an antenna), and/or chipset (such as a Bluetooth device, an 802.6 device (e.g. Metropolitan Area Network (MAN)), a Wi-Fi device, a WiMAX device, cellular communication facilities, etc.), and/or the like. Communication component 840 may permit data to be exchanged with any network such as a cellular network, a Wi-Fi network, a MAN, an optical network, etc., to name a few examples, and/or any other devices described in the present disclosure, including remote devices.

In some embodiments, communication component 840 may provide for communication within another device. For example, communication component 840 may include one or more interfaces. In some embodiments, communication component 840 may include logical distinctions on a single physical component, for example, multiple interfaces across a single physical cable or optical signal.

Modifications, additions, or omissions may be made to FIG. 16 without departing from the scope of the present disclosure. For example, computing device 800 may include more or fewer elements than those illustrated and described in the present disclosure. For example, computing device 800 may include an integrated display device such as a screen of a tablet or mobile phone or may include an external monitor, a projector, a television, or other suitable display device that may be separate from and communicatively coupled to computing device 800.

As used in the present disclosure, the terms “module” or “component” may refer to specific hardware implementations configured to perform the actions of the module or component and/or software objects or software routines that may be stored on and/or executed by general purpose hardware (e.g., computer-readable media, processing devices, etc.) of the computing system. In some embodiments, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated. In the present disclosure, a “computing entity” may be any computing system as previously defined in the present disclosure, or any module or combination of modulates running on a computing system.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

All examples and conditional language recited in the present disclosure are intended for pedagogical objects to aid the reader in understanding the invention and the concepts contributed by the inventor to furthering the art, and are to be construed as being without limitation to such specifically recited examples and conditions. Although embodiments of the present disclosure have been described in detail, various changes, substitutions, and alterations could be made hereto without departing from the spirit and scope of the present disclosure.

What is claimed is:

1. A method of measuring linearity characteristics of a delay line, comprising:
generating an output signal from a receiver including a delay line; and
measuring linearity characteristics of the delay line based on a target performance parameter of the output signal.

2. The method of claim 1, further comprising:
receiving an input data signal at the receiver;
receiving a phase code at the delay line of the receiver; and
adjusting at least one of a phase of the input data signal and the phase code to generate the target performance parameter for the output signal.

3. The method of claim 2, wherein the adjusting at least one of a phase of the input data signal and the phase code comprises adjusting at least one of the phase of the input data signal and the phase code to generate a target bit error rate (BER).

4. The method of claim 2, wherein the adjusting at least one of a phase of the input data signal and the phase code comprises adjusting at least one of the phase of the input data signal and the phase code to generate a target Q value.

5. The method of claim 4, wherein the adjusting at least one of the phase of the input data signal and the phase code to generate a target Q value comprises:
generating a plurality of measured Q values within a specified threshold range; and
calculating the target Q value from the plurality of measured Q values.

6. The method of claim 2, wherein the adjusting at least one of the phase of the input data signal and the phase code comprises adjusting the phase of the input data signal up to ⅛ of a resolution of a sampling clock generated by the delay line.

7. The method of claim 2, wherein the adjusting at least one of a phase of the input data signal and the phase code comprises adjusting the phase code with a delay selector of the receiver.

8. The method of claim 2, wherein the measuring linearity characteristics of the delay comprises comparing the output signal to the target performance parameter of the output signal for a plurality of received input data phase signals across a range of received phase codes.

9. The method of claim 1, wherein the measuring linearity characteristics of the delay line based on a target performance parameter of the output signal comprises determining a BER with an error counter coupled to an output of the receiver.

10. A method of measuring linearity characteristics of a delay line, the method comprising:
determining an associated phase of an input data signal for each phase code of a plurality of shifted phase codes conveyed to a delay line to generate a target performance parameter for an output signal; and
measuring linearity characteristics of the delay line based on two or more phase codes and associated phases of the input data signal.

11. The method of claim 10, wherein the determining comprises determining the associated phase of the input data signal for each phase code of the plurality of shifted phase codes conveyed to a delay line to generate a target bit error rate (BER) for the output signal.

12. The method of claim 10, wherein the determining comprises determining the associated phase of the input data signal for each phase code of the plurality of shifted phase codes conveyed to a delay line to generate a target bit error rate BER within a BER range.

13. The method of claim 10, wherein the determining an associated phase of the input data signal for each phase code of a plurality of shifted phase codes conveyed to a delay line circuit comprises:
setting a phase code;
generating the output signal; and
shifting the phase of an input data signal until the target performance parameter for the output signal is generated.

14. The method of claim 10, further comprising storing each phase code of the plurality of phase codes and the associated phases of the input data signal that generated the target performance parameter.

15. The method of claim 10, wherein the measuring linearity characteristics comprises generating a phase code versus phase of the input data signal plot.

16. The method of claim 10, wherein the determining comprises determining the associated phase of the input data signal for each phase code of the plurality of shifted phase codes conveyed to a delay line circuit to produce a target Q value for the output signal.

17. A device, comprising:
a phase shifter configured to convey input data signal;
a delay line configured to receive a reference clock signal and generate a sampling clock signal;
a delay selector configured to receive a phase code and convey a shifted phase code to the delay line;
a comparator configured to receive the input data signal and the sampling clock signal and generate an output signal; and
an error counter configured to receive and determine a bit error rate (BER) of the output signal.

18. The device of claim 17, further comprising a controller configured to:
determine a performance parameter of the delay line based on the BER of the output signal;
adjusting at least one of a phase of the input data signal and the phase code to generate the performance parameter within a target range; and
measuring linearity characteristics of the delay line based on each combination of the phase code and the phase of the input data signal to generate the performance parameter within the target range.

19. The device of claim 18, wherein the performance parameter comprises one of a BER and a Q value.

20. The device of claim 18, further comprising memory configured to store data related to each combination of the phase code and the phase of the input data signal.
